(19) United States
(12) Patent Application Publication
(10) Pub. No.: US 2018/0348419 A1
(43) Pub. Date: Dec. 6, 2018

(54) PHASE DIFFERENCE LAYER-PROVIDED POLARIZING PLATE AND IMAGE DISPLAY DEVICE

(71) Applicant: NITTO DENKO CORPORATION, Ibaraki-shi, Osaka (JP)

(72) Inventor: Toshiyuki Iida, Ibaraki-shi (JP)

(73) Assignee: NITTO DENKO CORPORATION, Ibaraki-shi, Osaka (JP)

(21) Appl. No.: 15/779,301

(22) PCT Filed: Nov. 18, 2016
(86) PCT No.: PCT/JP2016/084247

§ 371 Date: May 25, 2018

(30) Foreign Application Priority Data
Nov. 30, 2015 (JP) 2015-233761
Oct. 11, 2016 (JP) 2016-200418

(51) Int. Cl. G02B 5/30; G02F 1/13363; G02F 1/1335; H01L 27/32; H01L 51/52

(52) U.S. Cl. CPC G02B 5/3083; G02F 1/13363; G02F 1/133528; G02F 2001/133638; H01L 51/5293; G02F 2001/133637; H01L 27/32

(57) ABSTRACT

Provided is a polarizing plate with a retardation layer capable of realizing a liquid crystal display apparatus excellent in viewability when viewed through an optical member having polarizing action. The polarizing plate with a retardation layer has an elongate shape and includes, in this order: a retardation layer; a polarizer; and a pressure-sensitive adhesive layer. The retardation layer has an in-plane retardation Re(550) of from 100 nm to 180 nm, satisfies a relationship of Re(450)<Re(550)<Re(650), has a refractive index ellipsoid showing a relationship of nx>nz>ny, and has an Nz coefficient of from 0.2 to 0.8.

### TECHNICAL FIELD

The present invention relates to a polarizing plate with a retardation layer and an image display apparatus using the polarizing plate with a retardation layer.

### BACKGROUND ART

In recent years, there have been an increasing number of opportunities for use, under strong ambient light, of an image display apparatus, such as a cellular phone, a smartphone, a tablet per computer (PC), a car navigation system, digital signage, or a window display. In the case where the image display apparatus is used outdoors as described above, when a viewer looks at the image display apparatus while wearing polarized sunglasses, a transmission axis direction of the polarized sunglasses and a transmission axis direction of the image display apparatus on its output side may be brought into a state of crossed Nicols depending on an angle from which the viewer looks at the image display apparatus with the result that its screen may become black to prevent a display image from being viewed. In order to solve such problem, there has been proposed a technology involving arranging a λ/4 plate or an ultra-high retardation film on a viewer side of the image display apparatus. However, there is still large room for improvement in viewability at a time when the viewer locks at the image display apparatus while wearing polarized sunglasses.

### CITATION LIST

### Patent Literature

[PTL 1] JP 2005-352068 A

[PTL 2] JP 2011-107198 A

### SUMMARY OF INVENTION

### Technical Problem

The present invention has been made in order to solve the problem of the related art described above, and an object of the present invention is to provide a polarizing plate with a retardation layer capable of realizing a liquid crystal display apparatus excellent in viewability when viewed through an optical member having a polarizing action.

### Solution to Problem

According to one aspect of the present invention, a polarizing plate with a retardation layer is provided. The polarizing plate with a retardation layer has an elongate shape and includes, in this order: a retardation layer; a polarizer; and a pressure-sensitive adhesive layer, wherein the retardation layer has an in-plane retardation Re(550) of from 100 nm to 180 nm, satisfies a relationship of Re(450)<Re(550)<Re(650), has a refractive index ellipsoid showing a relationship of nx>nz>ny, and has an Nz coefficient of from 0.2 to 0.8.

In one embodiment of the invention, an angle formed between a slow axis of the retardation layer and an absorption axis of the polarizer is from 125° to 145°.

In one embodiment of the invention, the polarizing plate with a retardation layer further includes another retardation layer between the polarizer and the pressure-sensitive adhesive layer, wherein the another retardation layer has an in-plane retardation Re(550) of from 100 nm to 180 nm, and has a refractive index ellipsoid showing a relationship of nx>ny≥nz. In one embodiment of the invention, a slow axis of the retardation layer and a slow axis of the another retardation layer are substantially perpendicular to each other.

In one embodiment of the invention, the polarizing plate with a retardation layer further includes another retardation layer between the polarizer and the pressure-sensitive adhesive layer, wherein the another retardation layer has an in retardation Re(550) of from 150 nm to 350 nm, and has a refractive index ellipsoid showing a relationship of nx>nz>ny. In one embodiment of the invention, an angle formed between a slow axis of the retardation layer and a slow axis of the another retardation layer is from 35° to 55°.

In one embodiment of the invention, in-plane retardations of the another retardation layer satisfy a relationship of Re(450)<Re(550)<Re(650).

In one embodiment of the invention, the polarizing plate with a retardation layer further includes a separator temporarily bonded to an outer side of the pressure sensitive adhesive layer.

In one embodiment of the invention, the polarizing plate with a retardation layer has a roll shape.

According to another aspect of the present invention, an image display apparatus is provided. The image display apparatus includes the polarizing plate with a retardation layer, which is cut, on a viewer side, wherein the retardation layer of the polarizing plate with a retardation layer is arranged on the viewer side.

In one embodiment of the invention the image display apparatus comprises: a liquid crystal display apparatus including a backlight light source having a discontinuous emission spectrum; or an organic electroluminescence display apparatus.

### Advantageous Effects of Invention

According to the embodiment of the present invention, the retardation layer having the specific wavelength dispersion characteristic, in-plane retardation, refractive index ellipsoid, and Nz coefficient is arranged so as to be on the viewer side of the polarizer, and thus the polarizing plate with a retardation layer capable of realizing a liquid crystal display apparatus excellent in viewabiiity when viewed through an optical member having a polarizing action can be obtained.

### BRIEF DESCRIPTION OF DRAWINGS

FIG. 1 is a schematic sectional view of a polarizing plate with a retardation layer according to one embodiment of the present invention.

FIG. 2 is a schematic sectional view of a polarizing plate with a retardation layer according to another embodiment of the present invention.

FIG. 3 is a graph for schematically showing an example of the emission spectrum of a backlight light source that may be used for a liquid crystal display apparatus according to an embodiment of the present invention.

FIG. 4 is a graph for schematically showing an example of the emission spectrum of a related-art backlight light source.

### DESCRIPTION OF EMBODIMENTS

Typical embodiments of the present invention are described below. However, the present invention is not limited to these embodiments.

(Definitions of Terms and Symbols)

The definitions of terms and symbols used herein are as described below.

### (1) Refractive Indices (nx, ny, and nz)

“nx” represents a refractive index in a direction in which an in-plane refractive index is maximum (that is, slow axis direction), “ny” represents a refractive index in a direction perpendicular to the slow axis in the plane (that is, fast axis direction), and “nz” represents a refractive index in a thickness direction.

### (2) In-Plane Retardation (Re)

“Re(λ)” refers to an in-plane retardation of a film measured at 23° C. with light having a wavelength of λ nm. For example, “Re(450)” refers to an in-plane retardation of a film measured at 23° C. with light having a wavelength of 450 nm. The Re(λ) is determined from the equation “Re=(nx−ny)×d” when the thickness of a film is represented by d (nm).

### (3) Thickness Direction Retardation (Rth)

“Rth(λ)” refers to a thickness direction retardation of a film measured at 23° C. with light having a wavelength of 550 nm. For example, “Rth(450)” refers to a thickness direction retardation of a film measured at 23° C. with light having a wavelength of 450 nm. The Rth(λ) is determined from the equation “Rth=(nx−nz)×d” when the thickness of a film is represented by d (nm).

### (4) Nz Coefficient

Nz coefficient is determined from the equation “Nz=Rth/Re”.

(5) nx=ny, nx=nz, ny=nz

“nx=ny” encompasses not only a case in which nx and ny are exactly equal to each other, but also a case in which nx and ny are substantially equal to each other. The same applies to relationships of nx=nz and ny=nz.

### (6) Substantially Perpendicular or Parallel

The expressions “substantially perpendicular” and “approximately perpendicular” include a case in which an angle formed by two directions is 90°±10°, and the angle is preferably 90°±7°, more preferably 90°±5°. The expressions “substantially parallel” and “approximately parallel” include a case in which an angle formed by two directions is 0°±10° and the angle is preferably 0°±7°, more preferably 0°±5°. Moreover, such a simple expression “perpendicular” or “parallel” may include a substantially perpendicular state or a substantially parallel state.

### (7) Angle

When reference is made to an angle in this description, the angle encompasses angles in both clockwise and counterclockwise directions unless otherwise stated.

### (8) Elongate Shape

The term “elongate shape” means an elongated shape in which a length is sufficiently long as compared to a width, and includes, for example, an elongated shape in which a length is 10 or more times, preferably 20 or more times as long as a width.

### (9) Roll-to-Roll

The term “roll-to-roll” means that films each having a roll shape are bonded to each other with their lengthwise directions aligned with each other while being conveyed.

A. Polarizing Plate with Retardation Layer

A-1. Overall Configuration of Polarizing Plate with Retardation Layer

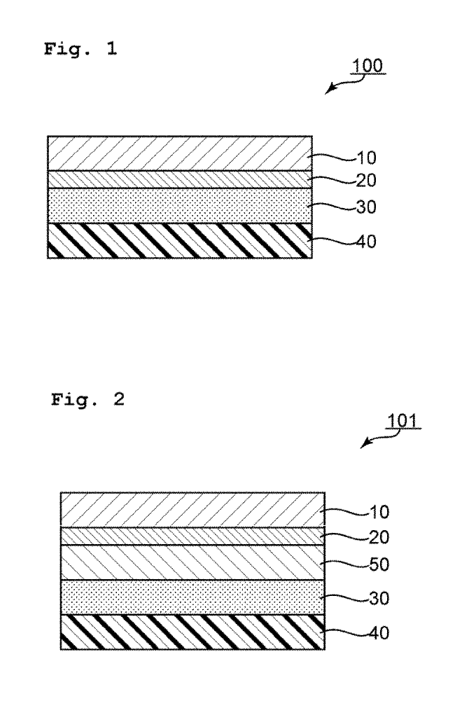

FIG. 1 is a schematic sectional view of a polarizing plate with a retardation layer according to one embodiment of the present invention. In the drawings, for ease of viewing, a ratio among the thicknesses of layers is different from an actual one. A polarizing plate 100 with a retardation layer according to this embodiment includes a retardation layer 10, a polarizer 20, and a pressure-sensitive adhesive layer 30 in the stated order. In the embodiment of the present invention, the retardation layer 10 has an in-plane retardation Re(550) of from 100 nm to 180 nm, preferably from 110 nm to 170 nm, more preferably from 120 nm to 160 nm, particularly preferably from 135 nm to 155 nm. Further, the retardation layer 10 satisfies a relationship of Re(450)<Re(550)<Re(650). In addition, the retardation layer 10 has a refractive index ellipsoid showing a relationship of nx>nz>ny, and has an Nz coefficient of from 0.2 to 0.8, preferably from 0.3 to 0.7, more preferably from 0.4 to 0.6, still more preferably about 0.5. An angle formed between the slow axis of the retardation layer 10 and the absorption axis of the polarizer 20 is preferably from 125° to 145°, more preferably from 128° to 142°, still more preferably from 130° to 140°, particularly preferably from 132° to 138°, especially preferably from 134° to 136°, most preferably about 135°.

FIG. 2 is a schematic sectional view of a polarizing plate with a retardation layer according to another embodiment of the present invention. A polarizing plate 101 with a retardation layer according to this embodiment further includes another retardation layer 50 between the polarizer 20 and the pressure-sensitive adhesive layer 30. For convenience, the retardation layer 10 is hereinafter sometimes referred to as first retardation layer, and the other retardation layer 50 is hereinafter sometimes referred to as second retardation layer. The second retardation layer 50 has an in-plane retardation Re(550) of preferably from 100 nm to 180 nm, more preferably from 110 nm to 170 nm, still more preferably from 120 nm to 160 nm, particularly preferably from 135 nm to 155 nm. Further, the second retardation layer 50 preferably satisfies a relationship of Re(450)<Re(550)<Re(650). In addition, the second retardation layer 50 has a refractive index ellipsoid preferably showing a relationship of nx>ny≥nz.

The in-plane retardation Re(550) of the second retardation layer 50 may be preferably from 150 nm to 350 nm. In this case, the refractive index ellipsoid of the second retardation layer preferably shows a relationship of nx>nz>ny. The in-plane retardation Re(550) of the second retardation layer 50 is more preferably from 180 nm to 320 nm, still more preferably from 240 nm to 300 nm. Also in this case, the second retardation layer preferably satisfies a relationship of Re(450)<Re(550)<Re(650).

In one embodiment, the slow axis of the first retardation layer 10 and the slow axis of the second retardation layer 50 are substantially perpendicular to each other. In this case, an angle formed between the slow axis of the second retardation layer 50 and the absorption axis of the polarizer 20 is preferably from 35° to 55°, more preferably from 38° to 52°, still more preferably from 40° to 50°, particularly preferably from 42° to 48°, especially preferably from 44° to 46°, most preferably about 45°. In this case, the second retardation layer preferably has an in-plane retardation Re(550) of from 100 nm to 180 nm, preferably satisfies a relationship of Re(450)<Re(550)<Re(650), and has a refractive index ellipsoid preferably showing a relationship of nx>ny≥nz. According to such configuration, the polarizing plate with a retardation layer can satisfactorily function as an antireflection film of an organic EL display apparatus. In another embodiment, an angle formed between the slow axis of the first retardation layer 10 and the slow axis of the second retardation layer 50 is preferably from 35° to 55°, more preferably from 38° to 52°, still more preferably from 40° to 50°, particularly preferably from 42° to 48°, especially preferably from 44° to 46°, most preferably about 45°. In this case, the slow axis of the second retardation layer 50 and the absorption axis of the polarizer 20 are substantially perpendicular to each other. In this case, the second retardation layer preferably has an in-plane retardation Re(550) of from 150 nm to 350 nm, preferably satisfies a relationship of Re(450)<Re(550)<Re(650), and has a refractive index ellipsoid preferably showing a relationship of nx>nz>ny. According to such configuration, the polarizing plate with a retardation layer can widen a viewing angle of a liquid crystal display apparatus.

The polarizing plate with a retardation layer according to each of the embodiments of the present invention has an elongate shape, which is not apparent from the drawings. Therefore, the constituent elements of the polarizing plate with a retardation layer (e.g., the polarizer, the first retardation layer, and the second retardation layer) each also have an elongate shape. The polarizer typically has an absorption axis in its elongate direction. Therefore, each of the first retardation layer and the second retardation layer may have a slow axis at the above-mentioned predetermined angle with respect to its elongate direction (that is, in an oblique direction). In one embodiment, the polarizing plate with a retardation layer is wound in a roll shape. The polarizing plate with a retardation layer may be produced by, for example, laminating, through a roll-to-roll process, an elongate retardation film constituting the first retardation layer 10, the elongate polarizer 20, and as required, an elongate retardation film constituting the second retardation layer 50.

As required, a protective film (not shown) may be arranged between the polarizer 20 and the first retardation layer 10, and/or between the polarizer 20 and the pressure-sensitive adhesive layer 30 (if present, the second retardation layer 50). Needless to say, the protective film also has an elongate shape.

As required, a conductive layer (not shown) may be arranged between the polarizer 20 (if present, the second retardation layer 50) and the pressure-sensitive adhesive layer 30. When the conductive layer is arranged, an image display apparatus using the polarizing plate with a retardation layer can constitute a so-called inner touch panel-type input display apparatus, which includes a built-in touch sensor between a display cell (e.g., a liquid crystal cell or an organic EL cell) and a polarizer.

In practical use, a separator 40 is temporarily bonded to the outer side of the pressure-sensitive adhesive layer 30 to protect the pressure-sensitive adhesive layer until the polarizing plate with a retardation layer is used, and to enable roll forming.

Now, each layer of the polarizing plate with a retardation layer is described.

A-2. First Retardation Layer

As described above, the in-plane retardation Re(550) of the first retardation layer 10 is from 100 nm to 180 nm, preferably from 110 nm to 170 nm, more preferably from 120 nm to 160 nm, particularly preferably from 135 nm to 155 nm. That is, the first retardation layer is capable of functioning as a so-called λ/4 plate. Further, the first retardation layer is arranged on the opposite side of the polarizer to the pressure-sensitive adhesive layer (so as to be on a viewer side when the polarizing plate with a retardation layer is applied to an image display apparatus). Therefore, the first retardation layer has a function of converting linearly polarized light, which is output from the polarizer toward the viewer side, into elliptically polarized light or circularly polarized light. Thus, when the first retardation layer capable of functioning as a λ/4 plate is arranged so as to be on the viewer side relative to the polarizer in the specific axis relationship as described above, there can be realized an image display apparatus having excellent viewability even when its display screen is viewed through an optical member having a polarizing action (e.g., polarized sunglasses). Therefore, an image display apparatus using the polarizing plate with a retardation layer of the present invention can be suitably used outdoors.

Further, as described above, the first retardation layer satisfies a relationship of Re(450)<Re(550)<Re(650). That is, the first retardation layer shows such reverse wavelength dispersion dependency that its retardation value increases with an increase in wavelength of measurement light. A ratio Re(450)/Re(550) of the first retardation layer is preferably 0.8 or more and less than 1.0, more preferably from 0.8 to 0.95. A ratio Re(550)/Re(650) of the first retardation layer is preferably 0.8 or more and less than 1.0, more preferably from 0.6 to 0.97.

The first retardation layer has a refractive index ellipsoid showing a relationship of nx>nz>ny as described above, and has a slow axis. As described above, the angle formed between the slow axis of the first retardation layer 10 and the absorption axis of the first polarizer 20 is preferably from 125° to 145°, more preferably from 128° to 142°, still more preferably from 130° to 140°, particularly preferably from 132° to 138°, especially preferably from 134° to 136°, most preferably about 135°. When the angle falls within such range, an extremely excellent circular polarization characteristic (consequently an extremely excellent antireflection characteristic) can be realized by using the first retardation layer as a λ/4 plate.

The Nz coefficient of the first retardation layer is preferably from 0.2 to 0.8, more preferably from 0.3 to 0.7, still more preferably from 0.4 to 0.5, particularly preferably about 0.5. When such relationship is satisfied, an image display apparatus having applied thereto the polarizing plate with a retardation layer has an advantage of being suppressed in coloration when being looked at from an oblique direction through an optical member having a polarizing action (e.g., polarized sunglasses).

The first retardation layer contains a resin having an absolute value of its photoelastic coefficient of preferably 2×10⁻¹¹ m²/N or less, more preferably from 2.0×10⁻¹³ m²/N to 1.5×10⁻¹¹ m²/N, still more preferably from 1.0×10⁻¹² m²/N to 1.2×10⁻¹¹ m²/N. When the absolute value of the photoelastic coefficient falls within such range, a retardation change is less liable to be generated in the case where a shrinkage stress is generated at the time of heating. As a result, heat unevenness in an image display apparatus using the polarizing plate with a retardation layer can be satisfactorily prevented.

The thickness of the first retardation layer may be set so that the first retardation layer can most appropriately function as a λ/4 plate. In other words, the thickness may be set so that a desired in-plane retardation can be obtained. Specifically, the thickness is preferably from 1 μm to 80 pμm, more preferably from 10 μm to 80 μm, still more preferably from 10 μm to 60 μm, particularly preferably from 30 μm to 50 μm.

The first retardation layer is formed of any appropriate resin that can satisfy the characteristics as described above. Examples of the resin for forming the first retardation layer include a polycarbonate resin, a polyvinyl acetal resin, a cycloolefin-based resin, an acrylic resin, and a cellulose ester-based resin. Of those, a polycarbonate resin is preferred.

As the polycarbonate resin, any appropriate polycarbonate resin may be used as long as the effect of the present invention is obtained. The polycarbonate resin preferably contains: a structural unit derived from a fluorene-based dihydroxy compound; a structural unit derived from an isosorbide-based dihydroxy compound; and a structural unit derived from at least one dihydroxy compound selected from the group consisting of an alicyclic diol, an alicyclic dimethanol, di-, tri-, or polyethylene glycol, and an alkylene glycol or spiroglycol. The polycarbonate resin more preferably contains: a structural unit derived from a fluorene-based dihydroxy compound; a structural unit derived from an isosorbide-based dihydroxy compound; and a structural unit derived from an alicyclic dimethanol and/or a structural unit derived from di-, tri-, or polyethylene glycol. The polycarbonate resin still more preferably contains: a structural unit derived from a fluorene-based dihydroxy compound; a structural unit derived from an isosorbide based dihydroxy compound; and a structural unit derived from di-, tri-, or polyethylene glycol. The polycarbonate resin may contain a structural unit derived from any other dihydroxy compound as required. Details of the polycarbonate resin that may be suitably used in the present invention are described in, for example, JP 2014-10291 A and JP 2014-26265 A. The descriptions of the publications are incorporated herein by reference.

The glass transition temperature of the polycarbonate resin is preferably 110° C. or more and 250° C. or less, more preferably 120° C. or more and 230° C. or less. When the glass transition temperature is excessively low, the heat resistance of the resin tends to deteriorate and hence the resin may cause a dimensional change after its forming into a film. In addition, the image quality of a liquid crystal display apparatus to be obtained may deteriorate. When the glass transition temperature is excessively high, the forming stability of the resin at the time of its forming into a film may deteriorate. In addition, the transparency of the film may be impaired. The glass transition temperature is determined in conformity to JIS K 7121 (1987).

The molecular weight of the polycarbonate resin may be expressed as a reduced viscosity. The reduced viscosity is measured with an Ubbelohde viscometer at a temperature of 20.0° C.±0.1° C. after precise adjustment of a polycarbonate concentration to 0.6 g/dL through the use of methylene chloride as a solvent. The lower limit of the reduced viscosity is generally preferably 0.30 dL/g, more preferably 0.35 dL/g or more. The upper limit of the reduced viscosity is generally preferably 1.20 dL/g, more preferably 1.00 dL/g, still more preferably 0.80 dL/g. When the reduced viscosity is lower than the lower limit value, there may arise a problem of a reduction in mechanical strength of a formed article. Meanwhile, when the reduced viscosity is higher than the upper limit value, there may arise a problem in that fluidity during forming is decreased to decrease productivity and formability.

The retardation film constituting the first retardation layer is obtained by, for example, stretching a film formed from the polycarbonate-based resin. Any appropriate forming method may be adopted as a method of forming a film from the polycarbonate-based resin. Specific examples thereof include a compression molding method, a transfer molding method, an injection molding method, an extrusion molding method, a blow molding method, a powder forming method, a FRP molding method, a cast coating method (such as a casting method), a calendar molding method, and a hot-press method. Of those, an extrusion molding method or a cast coating method is preferred. This is because the extrusion molding method or the cast coating method can increase the smoothness of the film to be obtained and provide satisfactory optical uniformity. Forming conditions may be appropriately set depending on, for example, the composition and kind of the resin to be used, and the desired characteristics of the retardation film.

The thickness of the resin film (unstretched film) may be set to any appropriate value depending on, for example, the desired thickness and desired optical characteristics of the retardation film to be obtained, and stretching conditions to be described later. The thickness is preferably from 50 μm to 300 μm.

Any appropriate stretching method and stretching conditions (such as a stretching temperature, a stretching ratio, and a stretching direction) may be adopted for the stretching. Specifically, one kind of various stretching methods, such as free-end stretching, fixed-end stretching, free-end shrinkage, and fixed-end shrinkage, may be employed alone, or two or more kinds thereof may be employed simultaneously or sequentially. With regard to the stretching direction, the stretching may be performed in various directions or dimensions, such as a lengthwise direction, a widthwise direction, a thickness direction, and an oblique direction.

A retardation film having the desired optical characteristics (such as a refractive index characteristic, an in-plane retardation, and an Nz coefficient) can be obtained by appropriately selecting the stretching method and stretching conditions.

In one embodiment, the retardation film may be produced by continuously subjecting a resin film having an elongate shape to oblique stretching in the direction of a predetermined angle with respect to a lengthwise direction. When the oblique stretching is adopted, a stretched film having an elongate shape and having an alignment angle that is a predetermined angle with respect to the lengthwise direction of the film (having a slow axis in the direction of the predetermined angle) is obtained, and for example, roll-to-roll manufacture can be performed in its lamination with the polarizer. As a result, the manufacturing process can be simplified. The predetermined angle may be an angle formed between the absorption axis of the polarizer (that is, the elongate direction of the film having an elongate shape) and the slow axis of the first retardation layer As described above, the angle is preferably from 125° to 145°, more preferably from 128° to 142°, still more preferably from 130° to 140°, particularly preferably from 132° to 138°, especially preferably from 134° to 136°, most preferably about 135°.

As a stretching machine to be used for the oblique stretching, for example, there is given a tenter stretching machine capable of applying feeding forces, or tensile forces or take-up forces, having different speeds on left and right sides in a lateral direction and/or a longitudinal direction. Examples of the tenter stretching machine include a lateral uniaxial stretching machine and a simultaneous biaxial stretching machine, and any appropriate stretching machine may be used as long as the resin film having an elongate shape can be continuously subjected to the oblique stretching.

Through appropriate control of each of the speeds on the left and right sides in the stretching machine, a retardation film (substantially a retardation film having an elongate shape) having the desired in-plane retardation and having a slow axis in the desired direction can be obtained.

As a method for the oblique stretching, there are given, for example, methods described in JP 50-83482 A, JP 02-113920 A, JP 03-182701 A, JP 2000-9912 A, JP 2002-86554 A, and JP 2002-22944 A.

A retardation film that may be suitably used in each of the embodiments of the present invention (that is, a retardation film having an Nz coefficient of less than 1.0) may be produced by bonding a heat-shrinkable film to one surface or each of both surfaces of the resin film through the intermediation of, for example, an acrylic pressure-sensitive adhesive to form a laminate, and subjecting the laminate to the stretching as described above. Through the adjustment of the configuration of the heat-shrinkable film (e.g., a shrinking force) and the stretching conditions (e.g., the stretching temperature), a retardation film having a desired Nz coefficient can be obtained.

The stretching temperature of the film may be changed depending on, for example, the desired in-plane retardation value and thickness of the retardation film, the kind of the resin to be used, the thickness of the film to be used, and a stretching ratio. Specifically, the stretching temperature is preferably from Tg−30° C. to Tg+30° C., more preferably from Tg−15° C. to Tg+15° C., most preferably from Tg−10° C. to Tg+10° C. When the stretching is performed at such temperature, a retardation film having characteristics that are appropriate in the present invention can be obtained. Tg refers to the glass transition temperature of the material constituting the film.

A commercially available film may be used as the polycarbonate-based resin film. Specific examples of the commercially available product include products manufactured by Teijin Limited under the product names “PURE-ACE WR-S”, “PURE-ACE WR-W”, and “PURE-ACE WR-M”, and a product manufactured by Nitto Denko Corporation under the product name “NRF”. The commercially available film may be used as it is, or the commercially available film may be subjected to secondary processing (e.g., stretching treatment or surface treatment) before use depending on purposes.

A-3. Polarizer

Any appropriate polarizer may be adopted as the polarizer. A resin film for forming the polarizer may be a single-layer resin film, or may be a laminate of two or more layers.

Specific examples of the polarizer formed of single-layer resin film include a product obtained by subjecting a hydrophilic polymer film, such as a polyvinyl alcohol (PVA)-based film, a partially formalized PVA-based film, or an ethylene-vinyl acetate copolymer-based partially saponified film, to dyeing treatment with a dichroic substance, such as iodine or a dichroic dye, and stretching treatment; and a polyene-based alignment film, such as a dehydration-treated product of PVA or a dehydrochlorination-treated product of polyvinyl chloride. Of those, a polarizer obtained by dyeing a PVA based film with iodine and uniaxially stretching the resultant is preferably used because of its excellent optical characteristics.

The dyeing with iodine is performed by, for example, immersing the PVA-based film in an aqueous solution of iodine. The stretching ratio of the uniaxial stretching is preferably from 3 times to 7 times. The stretching may be performed after the dyeing treatment or may be performed simultaneously with the dyeing. In addition, the stretching may be performed before the dyeing. The PVA-based film is subjected to, for example, swelling treatment, cross-linking treatment, washing treatment, or drying treatment as required. For example, when the PVA-based film is washed with water by being immersed in water before the dyeing, the soil or antiblocking agent on the surface of the PVA-based film can be washed off. In addition, the PVA-based film can be swollen to prevent dyeing unevenness or the like.

A specific example of the polarizer obtained by using a laminate is a polarizer obtained by using a laminate of a resin substrate and a PVA-based resin layer (PVA-based resin film) laminated on the resin substrate or a laminate of a resin substrate and a PVA-based resin layer formed on the resin substrate through application. The polarizer obtained by using the laminate of the resin substrate and the PVA-based resin layer formed on the resin substrate through application may be produced by, for example, a method involving: applying a PVA-based resin solution to the resin substrate; drying the solution to form the PVA-based resin layer on the resin substrate, thereby providing the laminate of the resin substrate and the PVA-based resin layer; and stretching and dyeing the laminate to turn the PVA-based resin layer into the polarizer. In this embodiment, the stretching typically includes the stretching of the laminate under a state in which the laminate is immersed in an aqueous solution of boric acid. The stretching may further include the aerial stretching of the laminate at high temperature (e.g., 95° C. or more) before the stretching in the aqueous solution of boric acid as required. The resultant laminate of the resin substrate and the polarizer may be used as it is (i.e., the resin substrate may be used as a protective layer for the polarizer). Alternatively, a product obtained as described below may be used: the resin substrate is peeled from the laminate of the resin substrate and the polarizer, and any appropriate protective layer in accordance with purposes is laminated on the peeling surface. Details of such method of producing a polarizer are described in, for example, JP 2012-73580 A. The entire description of the publication is incorporated herein by reference.

The thickness of the polarizer is preferably 15 μm or less, more preferably from 1 μm to 12 μm, still more preferably from 3 μm to 10 μm, particularly preferably from 3 μm to 8 μm. When the thickness of the polarizer falls within such range, curling at the time of heating can be satisfactorily suppressed, and satisfactory appearance durability at the time of heating is obtained. Further, when the thickness of the polarizer falls within such range, a contribution can be made to the thinning of an image display apparatus.

The polarizer preferably shows absorption dichroism at any wavelength in the wavelength range of from 380 nm to 780 nm. The single layer transmittance of the polarizer is preferably from 43.0% to 46.0%, more preferably from 44.5% to 46.0%. Thepolarization degree of the polarizer is preferably 97.0% or more, more preferably 99.0% or more, still more preferably 99.9% or more.

As described above, a protective film may be arranged on one side or each of both sides of the polarizer. The protective film is formed of any appropriate film. Specific examples of a material serving as a main component of the film include transparent resins, for example, a cellulose-based resin, such as triacetylcellulose (TAC), a polyester-based resin, a polyvinyl alcohol-based resin, a polycarbonate-based resin, a polyamide-based resin, a polyimide-based resin, a polyether sulfone-based resin, polysulfone-based resin, a polystyrene-based resin, a polynorbornene-based resin, a polyolefin-based resin, a (meth)acrylic resin, and an acetate-based resin. Another example thereof is a thermosetting resin or a UV-curable resin, such as a (meth)acrylic resin, a urethane-based resin, a (meth)acrylic urethane-based resin, an epoxy-based resin, or a silicone-based resin. Still another example thereof is a glassy polymer, such as a siloxane-based polymer. In addition, a polymer film described in JP 2001-343529 A (WO 01/37007 A1) may also be used. As a material for the film, for example, there may be used a resin composition containing thermoplastic resin having a substituted or unsubstituted imide group in a side chain and a thermoplastic resin having a substituted or unsubstituted phenyl group and a nitrile group in side chains. An example thereof is a resin composition containing an alternate copolymer formed of isobutene and N-methylmaleimide and an acrylonitrile-styrene copolymer. The polymer film may be, for example, a product obtained by subjecting the resin composition to extrusion molding.

The thickness of the protective film is preferably from 20 μm to 200 μm, more preferably from 30 μm to 100 μm, still more preferably from 35 μm to 95 μm.

When the protective film (inner protective film) is arranged on the opposite side of the polarizer to the first retardation layer, it is preferred that the inner protective film be optically isotropic. The phrase “be optically isotropic” as used herein refers to having an in-plane retardation Re(550) of from 0 nm to 10 nm and a thickness direction retardation Rth(550) of from −10 nm to +10 nm.

A-4. Second Retardation Layer

As described above, the in-plane retardation Re(550) of the second retardation layer 50 is from 100 nm to 180 nm, preferably from 110 nm to 170 nm, more preferably from 120 nm to 160 nm, particularly preferably from 135 nm to 155 nm. When the in-plane retardation of the second retardation layer falls within such range, a polarizing plate with a retardation layer capable of realizing an image display apparatus having an excellent antireflection characteristic can be obtained by arranging the second retardation layer at the specific axis angle as described above.

Further, as described above, the second retardation layer satisfies a relationship of Re(450)<Re(550)<Re(650).

The second retardation layer has a refractive index ellipsoid showing a relationship of nx>ny≥nz as described above, and has a slow axis. In this case, the slow axis of the first retardation layer 10 and the slow axis of the second retardation layer 50 are substantially perpendicular to each other as described above. With such configuration, the first retardation layer and the second retardation layer have symmetrical dimensional changes, and hence there can be obtained a polarizing plate with a retardation layer suppressed in curling and the like and excellent in durability. Further, for example, in an organic EL display apparatus, an excellent antireflection function can be realized. The Nz coefficient of the second retardation layer is preferably from 0.9 to 2, more preferably from 1 to 1.5, still more preferably from 1 to 1.3.

The other characteristics, constituent material, and the like of the second retardation layer are as described in the section A-2 for the first retardation layer. In addition, the description in the section A-2 for the first retardation layer is basically applicable also to a method of forming the second retardation layer. However, there is a difference in that the heat-shrinkable film is not used in the stretching of the second retardation layer.

As described above, a retardation film having an in-plane retardation Re(550) of from 150 nm to 350 nm, satisfying a relationship of Re(450)<Re(550)<Re(650) and having a refractive index ellipsoid showing a relationship of nx>nz>ny may be used as the second retardation layer. That is, the second retardation layer may have the same optical characteristics as those of the first retardation layer except the difference in in-plane retardation. With such configuration, for example, in a liquid crystal display apparatus, there is an advantage in that an excellent viewing angle characteristic can be realized. In this case, as described above, the angle formed between the slow axis of the first retardation layer 10 and the slow axis of the second retardation layer 50 is preferably from 35° to 55°, more preferably from 38° to 52°, still more preferably from 40° to 50°, particularly preferably from 42° to 46°, especially preferably from 44° to 46°, most preferably about 45°.

A-5. Pressure-Sensitive Adhesive Layer

Any appropriate pressure-sensitive adhesive may be used as a pressure-sensitive adhesive for forming the pressure-sensitive adhesive layer 30. The pressure-sensitive adhesive layer is typically formed of an acrylic pressure-sensitive adhesive. The thickness of the pressure-sensitive adhesive layer is, for example, from 10 μm to 50 μm.

A-6. Conductive Layer

The conductive layer is typically transparent (that is, the conductive layer is a transparent conductive layer). The conductive layer may be patterned as required. Through the patterning, a conductive part and an insulating part may be formed. As a result, an electrode may be formed. The electrode may function as a touch sensor electrode for detecting contact on a touch panel. The shape of the pattern is preferably a pattern that satisfactorily operates as a touch panel (e.g., a capacitance-type touch panel). Specific examples thereof include patterns described in, for example, 2011-511357 A, JP 2010-164938 A, JP 2008-310550 A, JP 2003-511799 A, and JP 2010-541109 A.

The total light transmittance of the conductive layer is preferably 80% or more, more preferably 85% or more, still more preferably 90% or more. For example, when a conductive nanowire to be described later is used, a transparent conductive layer having formed therein an opening can be formed, and hence a transparent conductive layer having a high light transmittance can be obtained.

The density of the conductive layer is preferably from 1.0 g/cm³ to 10.5 g/cm³, more preferably from 1.3 g/cm³ to 3.0 g/cm³.

The surface resistance value of the conductive layer is preferably from 0.1 Ω/□ to 1,000 Ω/□, more preferably from 0.5 Ω/□ to 500 Ω/□, still more preferably from 1 Ω/58 to 250 Ω/□.

Typical examples of the conductive layer include a conductive layer including a metal oxide, a conductive layer including a conductive nanowire, and a conductive layer including a metal mesh. Of those, a conductive layer including a conductive nanowire or a conductive layer including a metal mesh is preferred. This is because such material is excellent in bending resistance and hardly loses conductivity even when bent, and hence a conductive layer capable of being satisfactorily bent can be formed. As a result, the polarizing plate with a retardation layer can be applied to a bendable image display apparatus.

The conductive layer including a metal oxide may be formed by forming a metal oxide film on any appropriate substrate by any appropriate film formation method (e.g., a vacuum deposition method, a sputtering method, a CVD method, an ion plating method, or a spraying method). Examples of the metal oxide include indium oxide, tin oxide, zinc oxide, an indium-tin composite oxide, a tin-antimony composite oxide, a zinc-aluminum composite oxide, and an indium-zinc composite oxide. Of those, an indium-tin composite oxide (ITO) is preferred.

The conductive layer including a conductive nanowire may be formed by applying a dispersion liquid obtained by dispersing the conductive nanowire in a solvent (conductive nanowire dispersion liquid) onto any appropriate substrate, and then drying the applied layer. Any appropriate conductive nanowire may be used as the conductive nanowire as long as the effect of the present invention is obtained. The conductive nanowire refers to a conductive substance that has a needle- or thread-like shape and has a diameter of the order of nanometers. The conductive nanowire may be linear or may be curved. As described above, the conductive layer including the conductive nanowire is excellent in bending resistance. In addition, when the conductive layer including the conductive nanowire is used, pieces of the conductive nanowire form a gap therebetween to be formed into a network shape. Accordingly, even when a small amount of the conductive nanowire is used, a good electrical conduction path can be formed and hence a conductive layer having a small electrical resistance can be obtained. Further, the conductive nanowire is formed into a network shape, and hence an opening portion is formed in a gap of the network. As a result, a conductive layer having a high light transmittance can be obtained. Examples of the conductive nanowire include a metal nanowire containing a metal and a conductive nanowire including a carbon nanotube.

A ratio (aspect ratio: L/d) between a thickness d and a length L of the conductive nanowire is preferably from 10 to 100,000, more preferably from 50 to 100,000, still more preferably from 100 to 10,000. When a conductive nanowire having such large aspect ratio as described above is used, the conductive nanowire satisfactorily intersects with itself and hence high conductivity can be expressed with a small amount of the conductive nanowire. As a result, a conductive layer having a high light transmittance can be obtained. The term “thickness of the conductive nanowire” as used herein has the following meanings: when a section of the conductive nanowire has a circular shape, the term means the diameter of the circle; when the section has an elliptical shape, the term means the short diameter of the ellipse; and when the section has a polygonal shape, the term means the longest diagonal of the polygon. The thickness and length of the conductive nanowire may be observed with a scanning electron microscope or a transmission electron microscope.

The thickness of the conductive nanowire is preferably less than 500 nm, more preferably less than 200 nm, still more preferably from 1 nm to 100 nm, particularly preferably from 1 nm to 50 nm. When the thickness falls within such range, a conductive layer having a high light transmittance can be formed. The length of the conductive nanowire is preferably from 2.5 μm to 1,000 μm, more preferably from 10 μm to 500 μm, still more preferably from 20 μm to 100 μm. When the length falls within such range, a conductive layer having high conductivity can be obtained.

Any appropriate metal may be used as a metal for forming the conductive nanowire (metal nanowire) as long as the metal has high conductivity. The metal nanowire is preferably formed of one or more kinds of metals selected from the group consisting of gold, platinum, silver, and copper. Of those, silver, copper, or gold is preferred from the viewpoint of conductivity, and silver is more preferred. In addition, a material obtained by subjecting the metal to metal plating (e.g., gold plating) may be used.

Any appropriate carbon manotube may be used as the carbon nanotube. For example, a so-called multi-walled carbon nanotube, double-walled carbon nanotube, or single-walled carbon nanotube is used. Of those, a single-walled carbon nanotube is preferably used because of its high conductivity.

As the metal mesh, any appropriate metal mesh may be used as long as the effect of the present invention is obtained. For example, there may be used a metal wiring layer arranged on a film substrate and formed into a mesh pattern.

Details of the conductive nanowire and the metal mesh are described in, for example, JP 2014-113705 A and JP 2014-219667 A. The descriptions of the publications are incorporated herein by reference.

The thickness of the conductive layer is preferably from 0.01 μm to 10 μm, more preferably from 0.05 μm to 3 μm, still more preferably from 0.1 μm to 1 μm. When the thickness falls within such range, a conductive layer excellent in conductivity and light transmittance can be obtained. When the conductive layer includes the metal oxide, the thickness of the conductive layer is preferably from 0.01 μm to 0.05 μm.

The conductive layer may be used alone as a constituent layer of the polarizing plate with a retardation layer by transferring the conductive layer from the substrate on which the conductive layer has been formed onto the polarizer (or, if present, the inner protective film or the second retardation layer), or may be used as a constituent layer of the polarizing plate with a retardation layer by being laminated as a laminate with a substrate (conductive layer with a substrate) on the polarizer (or, if present, the inner protective film or the second retardation layer).

B. Image Display Apparatus

The polarizing plate with a retardation layer described in the section A, which has an elongate shape, may be cut into a predetermined size and applied to an image display apparatus. Therefore, the present invention encompasses an image display apparatus using such polarizing plate with a retardation layer. An image display apparatus according to an embodiment of the present invention includes a display cell and the polarizing plate with a retardation layer cut into a predetermined size (that is, a size corresponding to the display cell) on the viewer side thereof. The polarizing plate with a retardation layer is arranged so that the first retardation layer may be on the viewer side. Typical examples of the image display apparatus include a liquid crystal display apparatus and an organic EL display apparatus. In one embodiment, the image display apparatus is a liquid crystal display apparatus including a backlight light source having a discontinuous emission spectrum. Such backlight light source is described below. Configurations well known in the art may be adopted for overall configurations of the image display apparatus, such as the liquid crystal display apparatus and the organic EL display apparatus, and hence detailed description thereof is omitted.

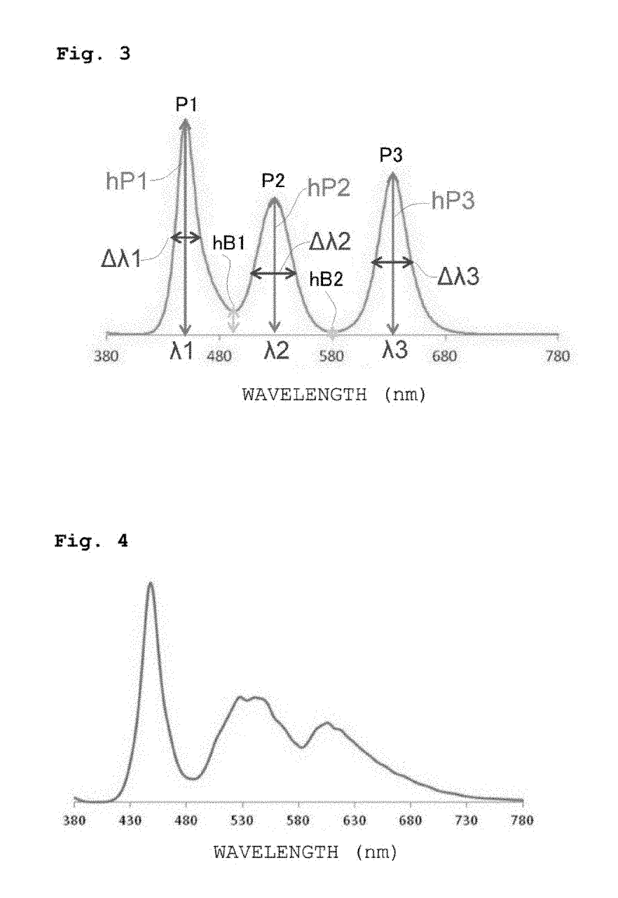

The backlight light source is included in a backlight unit of the liquid crystal display apparatus. As described above, the backlight light source has a discontinuous emission spectrum. The phrase “has a discontinuous emission spectrum” means that a distinct peak is present in each of the wavelength regions of red (R), green (G), and blue (B) and that the respective peaks are distinctly distinguished from each other. FIG. 3 is a graph for schematically showing an example of the discontinuous emission spectrum. As shown in FIG. 3, the emission spectrum of the backlight light source has a peak P1 in a wavelength region (blue wavelength region) of preferably from 430 nm to 470 nm, more preferably from 440 nm to 460 nm, a peak P2 in a wavelength region (green wavelength region) of preferably from 530 nm to 570 nm, more preferably from 540 nm to 560 nm, and a peak P3 in a wavelength region (red wavelength region) of preferably from 630 nm to 670 nm, more preferably from 640 nm to 660 nm. It is preferred that a wavelength λ1, a height hP1, and a half width Δλ1 of the peak P1, a wavelength λ2, a height hP2, and a half width Δλ2 of the peak P2, a wavelength λ3, a height hP3, and a half width Δλ3 of the peak P3, a height hB1 of a trough between the peak P1 and the peak P2, and a height hB2 of a trough between the peak P2 and the peak P3 satisfy the following relational expressions (1) to (3):

(λ2−λ1)/(Δλ2+Δλ1)>1 (1)

(λ3−λ2)/(Δλ3+Δλ2)>1 (2)

0.8≤(hP2−(hB2+hB1)/2)/hP2≤1 (3).

The (λ2/λ1)/(Δλ2+Δλ1) of the expression (1) is more preferably from 1.01 to 2.00, still more preferably from 1.10 to 1.50. The (λ3−λ2)/(Δλ3+Δλ2) of the expression (2) is more preferably from 1.01 to 2.00, still more preferably from 1.10 to 1.50. The (hP2−(hB2+hB1)/2) of the expression (3) is more preferably from 0.85 to 1, still more preferably from 0.9 to 1. The expression (1) means that blue light and green light have a relationship of being independent of each other without having a mixed color as light sources. The expression (2) means that green light and red light have a relationship of being independent of each other without having a mixed color as light sources. The expression (3) means that the troughs between the peaks P1, P2, and P3 are low and the peaks of blue light, green light, and red light are distinctly distinguished from each other. When the expressions (1) to (3) are specified, there is an advantage in that color reproducibility is improved. By virtue of the synergetic effect of the backlight light source 300 having the emission spectrum satisfying the expression (1) to the expression (3) and the first retardation layer 200, there can be realized a liquid crystal display apparatus excellent in color reproducibility, and excellent in viewability and suppressed in color unevenness when viewed through an optical member having a polarizing action. For example, as compared to a related-art backlight light source having an emission spectrum as shown in FIG. 3 (white light source obtained by merely combining LEDs that emit red light, green light, and blue light), the color reproducibility, and the viewability and the color unevenness at a time of viewing through an optical member having a polarizing action can all be remarkably improved.

The backlight light source is set to have any appropriate configuration that can realize the emission spectrum as described above. In one embodiment, the backlight light source includes an LED that emits a red color, an LED that emits a green color, and an LED that emits a blue color, and the phosphor of the LED that emits a red color is activated with a tetravalent manganese ion. When the phosphor of the LED that emits a red color is activated, an overlap between red light and green light in the emission spectrum shown in FIG. 4 can be reduced to realize the emission spectrum as shown in FIG. 3. Preferred specific examples of such red phosphor activated with the tetravalent manganese ion include: a Mn⁴⁺-activated Mg fluorogermanate phosphor (2.5MgO.MgF₂:Mn⁴⁺) given as an example in William M. Yen and Marvin J. Weber, “INORGANIC PHOSPHORS,” CRC Press, p. 212 (4.10 Miscellaneous Oxides in SECTION 4: PHOSPHOR DATA); and an M¹₂M²F₆:Mn⁴⁺ (M¹=Li, Na, K, Rb, Cs; M²=Si, Ge, Sn, Ti, Zr) phosphor given as an example in Journal of the Electrochemical Society: SOLID-STATE SCIENCE AND TECHNOLOGY, July 1973, p. 942. A backlight light source using such red phosphor is described in, for example, JP 2015-52648 A. In addition, a backlight light source of a general configuration including an LED that emits a red color, an LED that emits a green color, and an LED that emits a blue color is described in, for example, JP 2012-256014 A. The descriptions of those publications are incorporated herein by reference.

In another embodiment, the backlight light source includes an LED that emits a blue color and a wavelength conversion layer containing quantum dots. With such configuration, a part of blue light output from the LED is converted by the wavelength conversion layer into red light and green light, and another part of the blue light is output as it is as blue light. As a result, white light can be realized. Further, when the wavelength conversion layer is appropriately configured, an emission spectrum in which the peaks of red light, green light, and blue light are distinct and overlaps between the colors of light are small (emission spectrum as shown in FIG. 3) can be realized.

The wavelength conversion layer typically contains a matrix and quantum dots dispersed in the matrix. Any appropriate material may be used as a material for forming the matrix (hereinafter also referred to as matrix material). Examples of such material include a resin, an organic oxide, and an inorganic oxide. It is preferred that the matrix material have low oxygen permeability and low moisture permeability, have high light stability and high chemical stability, have a predetermined refractive index, have excellent transparency, and/or have excellent dispersibility of the quantum dots. In comprehensive consideration of the foregoing, the matrix material is preferably a resin. The resin may be a thermoplastic resin, may be a thermosetting resin, or may be an active energy ray-curable resin (e.g., an electron beam-curable resin, a UV-curable resin, or a visible light-curable resin). The resin is preferably a thermosetting resin or a UV-curable resin, more preferably a thermosetting resin. The resins may be used alone or in combination thereof (e.g., blended or copolymerized).

The quantum dots can control the wavelength conversion characteristic of the wavelength conversion layer. Specifically, when quantum dots having different center emission wavelengths are used in appropriate combination thereof, a wavelength conversion layer that realizes light having a desired center emission wavelength can be formed. The center emission wavelength of each of the quantum dots may be adjusted on the basis of, for example, the material and/or composition, particle size, and shape of each of the quantum dots. As the quantum dots, there are known, for example, quantum dots each having an center emission wavelength in a wavelength band ranging from 600 nm to 680 nm (hereinafter referred to as quantum dots A), quantum dots each having an center emission wavelength in a wavelength band ranging from 500 nm to 600 nm (hereinafter referred to as quantum dots B), and quantum dots each having an center emission wavelength in a wavelength band of from 400 nm to 500 nm (hereinafter referred to as quantum dots C). When excited by excitation light (in the present invention, light from the backlight light source), the quantum dots A emit red light, the quantum dots B emit green light, and the quantum dots C emit blue light. When those quantum dots are appropriately combined with each other, light having a center emission wavelength in a desired wavelength band can be realized by allowing light having a predetermined wavelength (light from the backlight light source) to enter and pass through the wavelength conversion layer.

The quantum dots may each be formed of any appropriate material. The quantum dots may each be formed of preferably an inorganic material, more preferably an inorganic conductor material or are inorganic semiconductor material. Examples of the semiconductor material include semiconductors of Groups II to VI, Groups III to V, Groups IV to VI, and Group IV. Specific examples thereof include Si, Ge, Sn, Be, Te, B, C (including diamond), P, BN, BP, BAs, AlN, AlP, AlAs, AlSb, GaN, GaP, GaAs, GaSb, InN, InP, InAs, InSb, ZnO, ZnS, ZnSe, ZnTe, CdS, CdSe, CdSeZn, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, (Al, Ga, In)₂(S, Se, Te)₃, and Al₂CO. Those materials may be used alone or in combination thereof. The quantum dots may each contain a p-type dopant or an n-type dopant.

Any appropriate size may be adopted as the size of each of the quantum dots depending on a desired emission wavelength. The size of each of the quantum dots is preferably from 1 nm to 10 nm, more preferably from 2 nm to 8 nm. When the size of each of the quantum dots falls within such range, sharp emission is shown for each of green light and red light, and a high color rendering property can be realized. For example, green light can be emitted when the size of each of the quantum dots is about 7 nm, and red light can be emitted when the size of each of the quantum dots is about 3 nm. When the quantum dots each have, for example, a true spherical shape, the size of each of the quantum dots is the average particle diameter, and when the quantum dots each have any other shape, the size is a dimension along the shortest axis in the shape. Any appropriate shape may be adopted as the shape of each of the quantum dots depending on purposes. Specific examples thereof include a true spherical shape, a flaky shape, a plate-like shape, an ellipsoidal shape, and an amorphous shape.

The quantum dots may be blended at a ratio of preferably from 1 part by weight to 50 parts by weight, more preferably from 2 parts by weight to 30 parts by weight with resipect to 100 parts by weight of the matrix material. When the blending amount of the quantum dots falls within such range, a liquid crystal display apparatus excellent in balance among all the RGB hues can be realized.

Details of the quantum dots are described in, for example, JP 2012-169271 A, JP 2015-102857 A, JP 2015-65158 A, JP 2013-544018 A, JP 2013-544018 A, and JP 2010-533975 A, and the descriptions of those publications are incorporated herein by reference. As the quantum dots, commercially available quantum dots may be used.

The thickness of the wavelength conversion layer is preferably from 1 μm to 500 μm, more preferably from 100 μm to 400 μm. When the thickness of the wavelength conversion layer falls within such range, the wavelength conversion layer can be excellent in conversion efficiency and durability.

The wavelength conversion layer is arranged as a film on the output side of the LED (light source) in the backlight unit.

### EXAMPLES

Now, the present invention is specifically described by way of Examples. However, the present invention is not limited by these Examples. Measurement methods for characteristics are as described below. In addition, in Examples, “part(s)” and “%” are by weight unless otherwise specified.

(1) Thickness

Measurement was performed with a dial gauge (manufactured by PEACOCK, product name: “DG-205”, dial gauge stand (product name: “pds-2”)).

### (2) Retardations

A sample measuring 50 mm by 50 mm was cut out of each retardation film and a liquid crystal fixed layer and was used as a measurement sample, and measurement was performed with Axoscan manufactured by Axometrics. Measurement wavelengths were 450 nm and 550 nm, and a measurement temperature was 23° C.

In addition, average refractive indices were measured with an Abbe refractometer manufactured by Atago Co., Ltd., and refractive indices nx, ny, and nz were calculated from the resultant retardation values.

### (3) Water Absorption Ratio

Measurement was performed in conformity to “Test Methods for Water Absorption and Boiling Water Absorption of Plastics” described in JIS K 7209. The size of a test piece was a square of 50 mm side, the test piece was immersed in water having a water temperature of 25° C. for 24 hours, and then a weight change before and after the water immersion was measured to determine a water absorption ratio. The unit is %.

### (4) Backlight Spectrum Measurement

A liquid crystal display apparatus obtained in Example 2 was caused to display a white image, and an emission spectrum was measured using SR-UL1R manufactured by Topcon Corporation. On the basis of the wavelength λ1, the wavelength λ2, the wavelength λ3, the height hP1, the height hP2, the height hP3, the height hB1, the height hB2, the half width Δλ1, the half width Δλ2, and the half width Δλ3 shown in FIG. 3 for the resultant emission spectrum, a light source satisfying the following expressions (1) to (3) was defined as a light source having a discontinuous spectrum. The spectrum of display light at a time when the liquid crystal display apparatus is caused to display the white image is roughly equal to the emission spectrum of the backlight light source. Therefore, the spectrum of display light at a time when the white image was displayed was defined as the emission spectrum of the backlight light source.

(λ2−λ1)/(Δλ2+Δλ1)>1 (1)

(λ3−λ2)/(Δλ3+Δλ2)>1 (2)

0.8≤(hP2−(hB2+hB1)/2)/hP2≤1 (3)

### (5) Viewability Evaluation

A display apparatus obtained in each of Examples and Comparative Examples was caused to display a white image, and viewability at a time when the image was observed through polarized sunglasses was evaluated in accordance with the following criteria. Satisfactory . . . Coloration and rainbow unevenness did not occur. Unsatisfactory . . . Coloration occurred.

### Example 1

### (Production of Retardation Film A Constituting First Retardation Layer)

Polymerization was performed with a batch polymerization apparatus formed of two vertical reactors each including a stirring blade and a reflux condenser controlled to 100° C. 9,9-[4-(2-Hydroxyethoxy)phenyl]fluorene (BHEPF), isosorbide (ISB), diethylene glycol (DEG), diphenyl carbonate (DPC), and magnesium acetate tetrahydrate were loaded at a molar ratio of BHEPF/ISB/DEG/DPC/magnesium acetate=0.348/0.490/0.162/1.005/1.00×10⁻⁵. The inside of a first reactor was sufficiently purged with nitrogen (oxygen concentration: 0.0005 vol % to 0.001 vol %), and then heated with a heating medium. When the internal temperature reached 100° C., stirring was started. The internal temperature was caused to reach 220° C. after 40 minutes from the start of the temperature increase, and while the temperature was controlled to be kept at this temperature, pressure reduction was simultaneously started, and the pressure was caused to reach 13.3 kPa in 90 minutes after the internal temperature had reached 220° C. A phenol vapor produced as a by-product along with the polymerization reaction was introduced into the reflux condenser at 100° C., a monomer component contained in a slight amount in the phenol vapor was returned to the first reactor, and a phenol vapor that did not condense was introduced into a condenser at 45° C. and recovered.

Nitrogen was introduced into the first reactor to temporarily return the pressure to the atmospheric pressure. After that, the oligomerized reaction liquid in the first reactor was transferred to a second reactor. Then, temperature increase and pressure reduction in the second reactor were started, and the internal temperature and the pressure were caused to reach 240° C. and 0.2 kPa, respectively in 50 minutes. After that, the polymerization was allowed to proceed until predetermined stirring power was achieved. When the predetermined power was achieved, nitrogen was introduced into the reactor to return the pressure to the atmospheric pressure, and the reaction liquid was extracted in the form of a strand and pelletized with a rotary cutter. Thus, a polycarbonate resin A having a copolymerization composition of BHEPF/ISB/DEG=34.8/49.0/16.2 [mol %] was obtained. The polycarbonate resin had a reduced viscosity of 0.430 dL/g and a glass transition temperature of 128° C.

The resultant polycarbonate resin was dissolved in methylene chloride to prepare a material for forming a birefringent layer. Then, the material for forming a birefringent layer was directly applied onto a shrinkable film (longitudinally uniaxially stretched polypropylene film, manufactured by Tokyo Printing Ink Mfg. Co., Ltd., product name: “NOBLEN”), and the applied film was dried at a drying temperature of 30° C. for 5 minutes and at a drying temperature of 80° C. for 5 minutes to form a laminate (60 μm) of the shrinkable film and a birefringent layer.

The resultant laminate was preheated to 142° C. in a preheating zone of a stretching apparatus. In the preheating zone, clip pitches of left and right clips were 125 mm. Next, simultaneously with the entry of the film into a first oblique stretching zone C1, the increase of the clip pitch of the right clips was started, and the clip pitch was increased from 125 mm to 177.5 mm in the first oblique stretching zone C1. A clip pitch change ratio was 1.42. In the first oblique stretching zone C1, with regard to the clip pitch of the left clips, the reduction of the clip pitch was started, and the clip pitch was reduced from 125 mm to 90 mm in the first oblique stretching zone C1. A clip pitch change ratio was 0.72. Further, simultaneously with the entry of the film into a second oblique stretching zone C2, the increase of the clip pitch of the left clips was started, and the clip pitch was increased from 90 mm to 177.5 mm in the second oblique stretching zone C2. Meanwhile, the clip pitch of the right clips was kept at 177.5 mm in the second oblique stretching zone C2. In addition, simultaneously with the oblique stretching, stretching was also performed in a widthwise direction at a ratio of 1.7 times. The oblique stretching was performed at 135° C. Then, in a shrinkage zone, MD shrinkage treatment was performed. Specifically, the clip pitches of both the left clips and the right clips were reduced from 177.5 mm to 160 mm. A shrinkage ratio in the MD shrinkage treatment was 10.0%. Through the stretching treatment, a retardation film A was formed on the shrinkable film. Then, the retardation film A was peeled from the shrinkable film.

Thus, a retardation film A (thickness: 60 μm) was obtained. The resultant retardation film A had an Re(550) of 140 nm, an Rth(550) of 70 nm, and a ratio Re(450)/Re(550) of 0.89. The slow axis direction of the retardation film A was 135° with respect to the lengthwise direction.

(Production of Polarizer)

An amorphous polyethylene terephthalate (A-PET) film (manufactured by Mitsubishi Plastics, Inc., product name: NovaClear SH046, 200 μm) was prepared as a substrate, and its surface was subjected to corona treatment (58 W/m²/min). Meanwhile, PVA (polymerization degree: 4,200, saponification degree: 99.2%) having added thereto 1 wt % of acetoacetyl-modified PVA (manufactured by the Nippon Synthetic Chemical Industry Co., Ltd., product name: Gohsefimer Z200 (polymerization degree: 1,200, saponification degree: 99.0% or more, acetoacetyl modification degree: 4.6%)) was prepared, ancl applied onto the substrate so as to have a film thickness after drying of 12 μm, followed by drying under a 60° C. atmosphere by hot-air drying for 10 minutes to produce a laminate in which a PVA-based resin layer was formed on the substrate.

Then, the laminate was first stretched in air at 130° C. at a ratio of 2.0 times in its MD direction to produce a stretched laminate. Next, there was performed a step of insolubilizing the PVA layer containing aligned PVA molecules included in the stretched laminate by immersing the stretched laminate in an insolubilizing aqueous solution of boric acid having a liquid temperature of 30° C. for 30 seconds. In the insolubilizing aqueous solution of boric acid in this step, the boric acid content was set to 3 parts by weight with respect to 100 parts by weight of water. The stretched laminate that had undergone the insolubilizing step was dyed to produce a colored laminate. The colored laminate is a product obtained by immersing the stretched laminate in a dyeing liquid to adsorb iodine onto the PVA layer included in the stretched laminate. The dyeing liquid contained iodine and potassium iodide, the liquid temperature of the dyeing liquid was set to 30° C., water was used as a solvent, the iodine concentration was set within the range of from 0.08 wt % to 0.25 wt %, and the potassium iodide concentration was set within the range of from 0.56 wt % to 1.75 wt %. A ratio between the concentrations of iodine and potassium iodide was set to 1 to 7. As dyeing conditions, the iodine concentration and the immersion time were set so that the PVA-based resin layer constituting a polarizer had a single layer transmittance of 40.9%.

Next, there was performed a step of subjecting the PVA molecules of the PVA layer onto which iodine had been adsorbed to cross-linking treatment by immersing the colored laminate in a cross-linking aqueous solution of boric acid at 30° C. for 60 seconds. In the cross-linking aqueous solution of boric acid to be used in this cross-linking step, the boric acid content was set to 3 parts by weight with respect to 100 parts by weight of water, and the potassium iodide content was set to 3 parts by weight with respect to 100 parts by weight of water. Further, the resultant colored laminate was stretched in an aqueous solution of boric acid at a stretching temperature of 70° C. at a ratio of 2.7 times in the same direction as that of the previous stretching in air so that the colored laminate was stretched at a final stretching ratio of 5.4 times, to thereby provide an optical film laminate including a polarizer to be tested. In the aqueous solution of boric acid to be used in this stretching step, the boric acid content was set to 4.0 parts by weight with respect to 100 parts by weight of water, and the potassium iodide content was set to 5 parts by weight with respect to 100 parts by weight of water. The resultant optical film laminate was removed from the aqueous solution of boric acid, and boric acid adhering to the surface of the PVA layer was washed off with an aqueous solution having a potassium iodide content of 4 parts by weight with respect to 100 parts by weight of water. The washed optical film laminate was dried by a drying step with warm air at 60° C. to provide an elongate polarizer laminated on the PET film, having a thickness of 5 μm, and having an absorption axis in its elongate direction.

(Production of Retardation Film B Constituting Second Retardation Layer)

A polycarbonate resin was obtained by the same method as the method by which the polycarbonate resin was obtained in the production of the retardation film A. The resultant polycarbonate resin was vacuum-dried at 80° C. for 5 hours, and then a polycarbonate resin film having a thickness of 130 μm was produced using a film-forming apparatus with a single-screw extruder (manufactured by Isuzu Kakoki, screw diameter: 25 mm, cylinder preset temperature: 220° C.), a T-die (width: 900 mm, preset temperature: 220° C.), a chill roll (preset temperature: 125° C.), and a take-up unit. The resultant polycarbonate resin film had a water absorption ratio of 1.2%.

The polycarbonate resin film was obliquely stretched by a method in conformity to Example 1 of JP 2014-194483 A to provide a retardation film B.

A specific production procedure for the retardation film B is as described below. The polycarbonate resin film (thickness: 130 μm, width: 765 mm) was preheated to 142° C. in a preheating zone of the stretching apparatus. In the preheating zone, clip pitches of left and right clips were 125 mm. Next, simultaneously with the entry of the film into a first oblique stretching zone C1, the increase of the clip pitch of the right clips was started, and the clip pitch was increased from 125 mm to 177.5 mm in the first oblique stretching zone C1. A clip pitch change ratio was 1.42. In the first oblique stretching zone C1, with regard to the clip pitch of the left clips, the reduction of the clip pitch was started, and the clip pitch was reduced from 125 mm to 90 mm in the first oblique stretching zone C1. A clip pitch change ratio was 0.72. Further, simultaneously with the entry of the film into a second oblique stretching zone C2, the increase of the clip pitch of the left clips was started, and the clip pitch was increased from 90 mm to 177.5 mm in the second oblique stretching zone C2. Meanwhile, the clip pitch of the right clips was kept at 177.5 mm in the second oblique stretching zone C2. In addition, simultaneously with the oblique stretching, stretching was also performed in a widthwise direction at a ratio of 1.9 times. The oblique stretching was performed at 135° C. Then, in a shrinkage zone, MD shrinkage treatment was performed. Specifically, the clip pitches of both the left clips and the right clips were reduced from 177.5 mm to 165 mm. A shrinkage ratio in the MD shrinkage treatment was 7.0%.

Thus, a retardation film B (thickness: 40 μm) was obtained. The resultant retardation film B had an Re(550) of 140 nm, an Rth(550) of 168 nm, and a ratio Re(450)/Re(550) of 0.89. The slow axis direction of the retardation film B was 45° with respect to the lengthwise direction.

(Production of Polarizing Plate with Retardation Layer)

The retardation film A was bonded to the surface of the polarizer produced as described above, the polarizer being laminated on the PET film and having a thickness of 5 μm, on the opposite side to the PET, through the intermediation of a UV-curable adhesive so that an angle formed between the slow axis of the retardation film A and the absorption axis of the polarizer was substantially 135°. Further, the PET film was peeled from the resultant laminate, and then the retardation film B was bonded to the surface of the polarizer on the opposite side to the retardation film A through the intermediation of a UV-curable adhesive so that the slow axis of the retardation film B and the slow axis of the retardation film A were substantially perpendicular to each other. Thus, an elongate polarizing plate with a retardation layer was produced.

(Production of Organic EL Display Apparatus)

A pressure-sensitive adhesive layer was formed on the retardation film B side of the resultant polarizing plate with a retardation layer through the use of an acrylic pressure-sensitive adhesive, and the resultant was cut into dimensions of 50 mm×50 mm.

A smartphone (Galaxy-S5 manufactured by Samsung Electronics Co., Ltd.) was disassembled to remove the organic EL panel of its organic EL display apparatus. A polarizing film bonded to the organic EL panel was peeled off, and the polarizing plate with a retardation layer cut into 50 mm×50 mm was bonded in place of the polarizing film through the intermediation of the pressure-sensitive adhesive layer to provide an organic EL panel. The organic EL panel having bonded thereto the polarizing plate with a retardation plate was mounted to the smartphone. Thus, an organic EL display apparatus of this Example was produced. The organic EL display apparatus was caused to display a white image, and viewability was evaluated through polarized sunglasses under the white image state. The result of the evaluation is shown in Table 1.

### Example 2

### (Production of Retardation Film C Constituting Second Retardation Layer)

In a reaction vessel with a stirring device, 27.0 kg of 2,2-bis(4-hydroxyphenyl)-4-methylpentane and 0.8 kg of tetrabutylammonium chloride were dissolved in 250 L of a sodium hydroxide solution. To the stirred solution, a solution of 13.5 kg of terephthaloyl chloride and 6.30 kg of isophthaloyl chloride dissolved in 300 L of toluene was added in one portion, and the mixture was stirred at room temperature for 90 minutes to provide a polycondensation solution. After that, the polycondensation solution was separated by being left to stand still to separate a toluene solution containing polyarylate. Then, the separated solution was washed with aqueous acetic acid and further washed with ion-exchanged water, and then charged into methanol to precipitate the polyarylate. The precipitated polyarylate was filtered and dried under reduced pressure to provide 34.1 kg of white polyarylate (yield: 92%).

10 kg of the resultant polyarylate was dissolved in 73 kg of toluene to prepare an application liquid. After that, the application liquid was directly applied onto a shrinkable film (longitudinally uniaxially stretched polypropylene film, manufactured by Tokyo Printing Ink Mfg. Co., Ltd., product name: “NOBLEN”), and the applied film was dried at a drying temperature of 60° C. for 5 minutes and at a drying temperature of 80° C. for 5 minutes to form a laminate of the shrinkable film and a birefringent layer. The resultant laminate was stretched at a ratio of 1.17 times in its TD direction at a stretching temperature of 155° C. and a shrinkage ratio in its MD direction of 0.80 through the use of a simultaneous biaxial stretching machine to form a retardation film C on the shrinkable film. Then, the retardation film C was peeled from the shrinkable film. The retardation film C had a thickness of 17 μm, an Re(550) of 270 nm, an Rth(550) of 135 nm, a ratio Re(450)/Re(550) of 1.10, and an Nz coefficient of 0.50. The slow axis direction of the retardation film C was 90° with respect to its lengthwise direction.

(Production of Polarizing Plate with Retardation Layer)

A polarizing plate with a retardation layer was produced in the same manner as in Example 1 except that the retardation film A was bonded so that the angle formed between its slow axis and the absorption axis of the polarizer was substantially 45°; and the retardation film C was used in place of the retardation film B, and the retardation film C was bonded so that an angle formed between its slow axis and the slow axis of the retardation film A was substantially 45° and that the slow axis of the retardation film C and the absorption axis of the polarizer were substantially perpendicular to each other.

(Production of Liquid Crystal Display Apparatus)

A liquid crystal panel was removed from the liquid crystal display apparatus of a smartphone including a liquid crystal display apparatus of an IPS mode (Xperia Z4 manufactured by Sony Corporation: including a backlight having a discontinuous emission spectrum), a polarizing plate arranged on the viewer side of the liquid crystal cell was removed, and the glass surface of the liquid crystal cell was cleaned. Subsequently, the surface of the polarizing plate with a retardation plate on its retardation film C side was laminated on the surface of the liquid crystal cell on its viewer side through the intermediation of an acrylic pressure-sensitive adhesive (thickness: 20 μm) so that the absorption axis of the polarizer was perpendicular to the initial alignment direction of the liquid crystal cell to provide a liquid crystal panel. The liquid crystal panel having laminated thereon the polarizing plate with a retardation plate was mounted to the smartphone. Thus, a liquid crystal display apparatus of this Example was produced. The liquid crystal display apparatus was caused to display a white image, and viewability was evaluated through polarized sunglasses under the white image state. The result of the evaluation is shown in Table 1.

### Comparative Example 1

### (Production of Retardation Film D Constituting First Retardation Layer)

A commercially available Arton film (manufactured by JSR Corporation, thickness: 70 μm) was stretched to provide a retardation film D. The resultant retardation film D had an Re(550) of 140 nm, an Rth(550) of 168 nm, and a ratio Re(450)/Re(550) of 1.00. The slow axis direction of the retardation film D was 135° with respect to its lengthwise direction.

(Production of Polarizing Plate with Retardation Layer)

A polarizing plate with a retardation layer was produced in the same manner as in Example 1 except that: the retardation film D was used in place of the retardation film A, and was bonded so that an angle formed between its slow axis and the absorption axis of the polarizer was substantially 45°; and the retardation film B was bonded so that its slow axis and the slow axis of the retardation film D were substantially perpendicular to each other.

(Production of Organic EL Display Apparatus)

An organic EL display apparatus was produced in the same manner as in Example 1 except that the above-mentioned polarizing plate with a retardation layer was used. The organic EL display apparatus was caused to display a white image, and viewability was evaluated through polarized sunglasses under the white image state. The result of the evaluation is shown in Table 1.

### Comparative Example 2

### (Production of Retardation Film E Constituting First Retardation Layer)

With the use of phosgene as a carbonate precursor, and (A) 2,2-bis(4-hydroxyphenyl)propane and (B) 1,1-bis(4-hydroxyphenyl)-3,3,5-trimethylcyclohexane as aromatic dihydric phenol components, a polycarbonate-based resin having a weight ratio (A):(B) of 4:6 and a weight-average molecular weight (Mw) of 60,000, and containing repeating units represented by the following chemical formulae (I) and (II) (number average molecular weight (Mn)=33,000, Mw/Mn=1.78) was obtained in accordance with a conventional method. 70 Parts by weight of the polycarbonate-based resin and 30 parts by weight of a styrene-based resin having a weight-average molecular weight (Mw) of 1,300 (number-average molecular weight (Mn)=716, Mw/Mn=1.78) (HIMER SB75 manufactured by Sanyo Chemical Industries, Ltd.) were added to 300 parts by weight of dichloromethane, and the components were mixed by stirring under room temperature for 4 hours to provide a transparent solution. The solution was cast onto a glass plate, left to stand at room temperature for 15 minutes, and then peeled from the glass plate, followed by drying in an oven at 80° C. for 10 minutes and at 120° C. for 20 minutes to provide a polymer film having a thickness of 40 μm and a glass transition temperature (Tg) of 140° C. The resultant polymer film had a light transmittance at a wavelength of 590 nm of 93%. In addition, the polymer film had an in-plane retardation value: Re(590) of 5.0 nm and a thickness direction retardation value: Rth(590) of 12.0 nm. Its average refractive index was 1.576.

The resultant polymer film was stretched to provide a retardation film E. The resultant retardation film E had an Re(550) of 140 nm, an Rth(550) of 168 nm, and a ratio Re(450)/Re(550) of 1.06. The slow axis direction of the retardation film E was 135° with respect to its lengthwise direction.

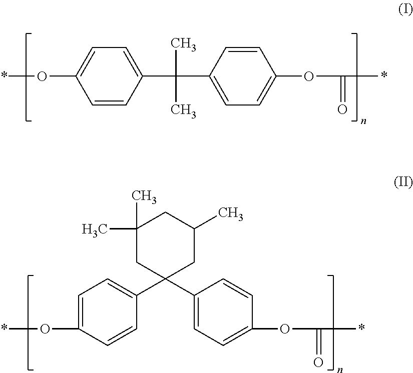

(Production of Polarizing Plate with Retardation Layer)

A polarizing plate with a retardation layer was produced in the same manner as in Example 1 except that: the retardation film E was used in place of the retardation film A, and was bonded so that an angle formed between its slow axis and the absorption axis of the polarizer was substantially 45°; and the retardation film B was bonded so that its slow axis and the slow axis of the retardation film E were substantially perpendicular to each other.

(Production of Organic EL Display Apparatus)

An organic EL display apparatus was produced in the same manner as in Example 1 except that the above-mentioned polarizing plate with a retardation layer was used. The organic EL display apparatus was caused to display a white image, and viewability was evaluated through polarized sunglasses under the white image state. The result of the evaluation is shown in Table 1.

TABLE 1

| | First retardation layer | | | | |
|---|---|---|---|---|---|
| | | | Wavelength dispersion | | |
| | | In-plane retardation | characteristic | | |
| | Refractive indices | Re550 (nm) | (Re450/Re550) | Nz coefficient | Alignment angle |
| Example 1 | nx > nz > ny | 140 | 0.89 | 0.5 | 135 |
| Example 2 | nx > nz > ny | 140 | 0.89 | 0.5 | 135 |
| Comparative | nx > ny > nz | 140 | 1.00 | 1.2 | 135 |
| Example 1 | | | | | |
| Comparative | nx > ny > nz | 140 | 1.06 | 1.2 | 135 |
| Example 2 | | | | | |

| | Second retardation layar | | | | | | |
|---|---|---|---|---|---|---|---|
| | | In-plane | Wavelength | | | | |
| | | retardation | dispersion | | | | |
| | Refractive | Re550 | characteristic | Nz | Alignment | Light | |
| | indices | (nm) | (Re450/Re550) | coefficient | angle | source | Viewability |
| Example 1 | nx > ny > nz | 140 | 0.89 | 1.2 | 45 | Organic | Satisfactory |
| | | | | | | EL | |
| Example 2 | nx > nz > ny | 270 | 1.10 | 0.5 | 90 | Backlight | Satisfactory |
| | | | | | | (discontinuous | |
| | | | | | | spectrum) | |
| Comparative | nx > ny > nz | 140 | 0.89 | 1.2 | 45 | Organic | Unsatisfactory |
| Example 1 | | | | | | EL | |
| Comparative | nx > ny > nz | 140 | 0.89 | 1.2 | 45 | Organic | Unsatisfactory |
| Example 2 | | | | | | EL | |

### INDUSTRIAL APPLICABILITY

The polarizing plate with a retardation layer of the present invention is suitably used in an image display apparatus, such as a liquid crystal display apparatus or an organic EL display apparatus.

### REFERENCE SIGNS LIST

10 first retardation layer

20 polarizer

30 pressure-sensitive adhesive layer

40 separator

50 second retardation layer

100 polarizing plate with retardation layer

101 polarizing plate with retardation layer

1. A polarizing plate with a retardation layer, having an elongate shape and comprising, in this order:
a retardation layer;
a polarizer; and
a pressure-sensitive adhesive layer,
wherein the retardation layer has an in-plane retardation Re(550) of from 100 nm to 180 nm, satisfies a relationship of Re(450)<Re(550)<Re(650), has a refractive index ellipsoid showing a relationship of nx>nz>ny, and has an Nz coefficient of from 0.2 to 0.8.

2. The polarizing plate with a retardation layer according to claim 1, wherein an angle formed between a slow axis of the retardation layer and an absorption axis of the polarizer is from 125° to 145°.

3. The polarizing plate with a retardation layer according to claim 1, further comprising another retardation layer between the polarizer and the pressure-sensitive adhesive layer, wherein the another retardation layer has an in-plane retardation Re(550) of from 100 nm to 180 nm, and has a refractive index ellipsoid showing a relationship of nx>ny>nz.

4. The polarizing plate with a retardation layer according to claim 1, further comprising another retardation layer between the polarizer and the pressure-sensitive adhesive layer, wherein the another retardation layer has an in-plane retardation Re(550) of from 150 nm to 350 nm, and has a refractive index ellipsoid showing a relationship of nx>nz>ny.

5. The polarizing plate with a retardation layer according to claim 3, wherein a slow axis of the retardation layer and a slow axis of the another retardation layer are substantially perpendicular to each other.

6. The polarizing plate with a retardation layer according to claim 4, wherein an angle formed between a slow axis of the retardation layer and a slow axis of the another retardation layer is from 35° to 55°.

7. The polarizing plate with a retardation layer according to claim 5, wherein in-plane retardations of the another retardation layer satisfy a relationship of Re(450)<Re(550)<Re(650).

8. The polarizing plate with a retardation layer according to claim 1, further comprising a separator temporarily bonded to an outer side of the pressure-sensitive adhesive layer.

9. The polarizing plate with a retardation layer according to claim 1, wherein the polarizing plate with a retardation layer has a roll shape.

10. An image display apparatus, comprising the polarizing plate with a retardation layer of claim 1, which is cut, on a viewer side, wherein the retardation layer of the polarizing plate with a retardation layer is arranged on the viewer side.

11. The image display apparatus according to claim 10, wherein the image display apparatus comprises:
a liquid crystal display apparatus including a backlight light source having a discontinuous emission spectrum; or
an organic electroluminescence display apparatus.
